(19) United States
(12) Patent Application Publication
(10) Pub. No.: US 2026/0304671 A1
(43) Pub. Date: Oct. 1, 2026

(54) SYSTEM, METHOD AND ARRANGEMENT FOR ENERGY STORAGE AND SUPPLY

(71) Applicant: Luis CASLA URTEAGA, Alcobendas (ES)

(72) Inventor: Luis CASLA URTEAGA, Alcobendas (ES)

(21) Appl. No.: 18/998,098

(22) PCT Filed: Jul. 26, 2023
(86) PCT No.: PCT/EP2023/025350

§ 371 Date: Jan. 23, 2025

(30) Foreign Application Priority Data
Jul. 26, 2022 (ES) U202231241
Apr. 5, 2023 (ES) U202330583

(51) Int. Cl. H05K 7/14; H01M 10/46; H02J 7/00; H02J 7/35; H02M 7/00

(52) U.S. Cl. CPC H05K 7/1432; H01M 10/465; H02J 7/35; H02J 7/855; H02M 7/003; H01M 2220/30

(57) ABSTRACT

Power station comprising inverter (1) and battery modules (2) utilized to support self-consumption solar systems or to replace or hybridize fuel-based electrical generators, and designed to be operable both in portable mode for stand-alone use and in fixed operational mode integrated in private electrical installations. In portable mode both elements are positioned facing each other on a transport element such as a trolley. In fixed mode both elements can be independently mounted on the wall, occupying minimal space and connected to the private electrical installation via the electrical board. Each battery module (2) comprises a front battery fastener (2.1) attachable to a rear battery fastener (2.2) or to a rear inverter fastener (1.3) comprised in the inverter (1) in portable mode. In fixed mode the inverter (1) and each battery module (2) are separately attachable to a wall via an inverter wall-fastener (4.3) and a battery wall-fastener (4.4) respectively.

### TECHNICAL FIELD

The present invention pertains to the field of electrical power systems, specifically arrangements for energy storage and supply that comprise an inverter and a battery which might be also called power stations. These arrangements are typically utilized to support self-consumption solar systems or to replace or hybridize existing fuel-based electrical generators. The ideal inverter to be integrated into this invention would preferably be single-phased, inclusive of a charge controller, and hybrid, as it comprises an AC input for a backup source that can be utilized with the electrical grid or a fuel generator.

The object of the present invention is to offer a novel configuration of the mentioned elements, namely, the inverter and battery, designed to maintain their separability for usage in two distinct modes. Firstly, a portable operational mode intended for use in isolated locations, where both elements are positioned facing each other, particularly in a transport element such as a trolley. Secondly, a fixed mode incorporated within electrical installations, wherein both elements can be independently mounted on the wall, occupying minimal space and connected via the electrical board.

### BACKGROUND OF THE INVENTION

The inverter and the battery, together with the photovoltaic panels are the three main elements of a solar self-consumption generator. The inverter transforms direct current from the panels or the battery into alternating current used to supply the loads of the installation, and the battery allows storing the generation surpluses for later use when solar radiation is no longer enough to supply the loads. The inverter type mentioned (single-phased, hybrid and with integrated charge controller) has a CC input for the panels, a CC input and output for the battery, an AC output to supply the loads of the installation and a CA input to ensure uninterrupted supply that in fixed private installations will be connected to the electrical grid and in isolated locations to fuel generators.

Portable solar systems comprising at least the 3 mentioned elements: inverter, battery and portable solar panels, are experiencing a rapid development in recent times for outdoor activities in locations with no access to the electrical grid, in replacement or to hybridize traditional fuel generators. For these cases several solutions are currently known in which both mentioned elements, inverter and battery, are designed inside a compact unit of cubic format.

The main disadvantage of these compact solutions is that in the case of high power, the size and weight are excessive, making portability difficult, which is the essence of these systems. Another disadvantage is that these solutions can only be used in portable mode and cannot be integrated into private installations.

In the case of solar self-consumption systems for private installations in which storage in batteries is used and in which the arrays of photovoltaic panels are installed permanently on roofs, façades, gardens and terraces, current solutions are always fixed and the two mentioned elements, inverter and battery, are generally installed separately close to the board of the electrical installation in which they are integrated. A significant number of inverters are designed for being mounted on the wall, while the batteries, due to their great weight and volume, are installed either on the floor under the inverter or in adjoining rooms where their excessive volume is not a problem. One known solution in the prior art is the Powerwall solution from TESLA, in which the battery is designed with a flattened format in which the depth is reduced at the expense of a considerable increase in its height and width dimensions. This way the unit can be used in wall-mounted mode, thus reducing the volume projected into the interior of the room.

The main disadvantage of these private installation solutions is that they are intended to be fixed and cannot be disassembled by the user for occasional use in portable mode so as to use as a power station in remote locations.

### DESCRIPTION OF THE INVENTION

The present invention intends to solve at least one of the aforementioned disadvantages.

An object of the present invention is to provide an arrangement of the battery and the inverter that facilitates dual usage, specifically, that it is operational in both a portable and fixed modes, with provisions made for ease of transition between these modes. Additionally, the invention aims to overcome the challenge of portability caused by the excessive weight of the battery and the inverter, enabling independent transport and better handling of the equipment. This invention also addresses the need to minimize the volume that the battery and the inverter project into a room when used in the fixed operational mode and connected to an existing electrical installation. It's important to note that the considerable widths of traditional inverters and batteries often make them unsuitable for wall-mounting in residential, commercial and business spaces.

More specifically, the first aspect of the invention pertains to an arrangement for energy storage and supply, potentially marketed as an electric power station. This arrangement introduces several new components and a set of adaptive elements to the hybrid inverter and to at least one battery module. These modifications facilitate their separation and allow their utilization in two distinct modes: on one hand, a portable mode for usage in isolated environments, wherein the inverter and at least one battery module are fastened face-to-face, preferably on a transport element such as a trolley; on the other hand, a fixed mode for use in private electrical installations, where both components are wall-mounted adjacent to the electrical board of the electrical installation.

Throughout the present description, it should be understood, if not explicitly mentioned, that a battery comprises at least a battery module.

In addition, within the meaning of the invention, fasteners, as mentioned in the context of this description, are fundamentally devices or mechanisms that can enable the attachment and detachment of the key components, in this case, the inverter and the battery. Fasteners can encompass a wide range of designs and mechanisms, such as clips, clamps, couplings, brackets, hooks, or even magnetic, adhesive, or Velcro solutions, as long as they serve the primary purpose of securely joining these components together, while allowing for their easy separation when needed. The exact form or structure of these fasteners is not strictly defined and could vary significantly depending on the specific needs and constraints of the application, material used, weight considerations, and other factors. It is clearly understood by those skilled in the art that any equivalent means capable of fulfilling the basic function of attaching and detaching these components fall within the scope and spirit of the invention.

In a first aspect of the invention, it is provided an arrangement for energy storage and supply, comprising an inverter and at least a battery module, wherein the inverter and the at least a battery module are attachable and detachable in such a way as to determine:
a fixed operational mode, with the inverter and the at least a battery module unattached to one another, wherein the inverter is configured to be connected to an electrical installation for self-consumption,
a portable operational mode, with the inverter and the at least a battery module attached to one another for ease of transportation, in particular with the inverter electrically disconnected from the electrical installation and physically removed thereof,
wherein the at least a battery module comprises a first battery fastener attachable to an inverter mounting comprised in the inverter, wherein the first fastener and the inverter fastener are configured to be used in the portable mode with the inverter attached to the at least a battery module thereof.

The first battery fastener as mentioned above might be preferably a front battery fastener, but alternative configurations or placements could be conceived by a skilled person for similar solutions, all within the spirit of the present invention. Similarly, while the inverter fastener might be considered a rear fastener in a preferred embodiment of the invention, other configurations or placements could be directly envisioned that align with the objective and spirit of the invention, thus not confining the invention to a rear-placed fastener or to a front-placed battery fastener.

In some embodiments, the arrangement or power station further comprises an inverter wall-fastener intended to be attached to a wall or to any vertical surface during the fixed operational mode, wherein the inverter fastener is further attachable with said inverter wall-fastener. Note that, in this embodiment the inverter fastener is attachable to the at least a battery and also to the inverter wall-fastener.

Alternatively, the inverter might further comprise second inverter fastener attachable with the inverter wall-fastener, so that the inverter fastener aforementioned intended for attachment with the battery fastener is different that the second inverter fastener herein described which is for wall attachment.

In the context of this invention, the term “wall” is intended to refer broadly to any surface or structural element that can serve as a support for the elements of the arrangement. It's important to note that this isn't limited to traditional building walls but can also encompass any vertical support structure that can accommodate the fasteners and equipment. This could include, for example, dedicated mounting boards, a structural column, a pillar, a partition wall, or even a specially designed freestanding frame or rack. In essence, any surface or structure that provides stability and is suitable for mounting the components of the arrangement can serve as the “wall” in the context of this invention.

In some embodiments, the arrangement further includes a battery wall-fastener intended for attachment to a wall or any vertical surface during the fixed operational mode. Here, the battery module, or at least one of them, may be equipped with a second battery fastener that can engage with this battery wall-fastener. This fastener is specifically designed for use in the fixed operational mode, particularly when the battery module is electrically connected to, but not physically attached to, the inverter. Thus, in the fixed operational mode, the battery modules can be mounted on the wall using these second battery fasteners.

The second battery fastener may, without being limited to be a rear fastener, that is, a fastener arranged on the rear face of the battery whereas first battery fasteners may be front battery fasteners. However, other configurations and solutions can be conceived by those skilled in the art, falling within the spirit and objectives of the present invention.

Alternatively, the first battery fastener can be attached to the battery wall-fastener. In this configuration, the first battery fastener can connect with both the inverter fastener and the wall fastener, thereby eliminating the need for a second battery fastener.

In certain embodiments, the second battery fastener can also be attached to a transportation device, which includes a transportation fastener that is connectable to the said second battery fastener. This facilitates easy transport during the portable operational mode.

Optionally, the transportation device comprises a trolley, wherein said trolley comprises a plurality of wheels and a frame provided with the transportation fastener attachable with the second fastener of the at least a battery.

In some embodiments, the inverter might be a single-phase model preferably integrated with a flattened format, having a depth of preferably less than 12 cm and therefore considerably reduced with respect to its width and height. This same format is used for the design of the battery whose maximum depth is limited to 15 cm. In this way the two resulting volumes project minimally into the room when used in wall-mounted configuration hanging on the wall, and the volume is also as compact as possible for use in portable mode in which the inverter is placed in front of the battery, coupled to a transport element that can be for example a trolley.

The mentioned flattened format allows the placement of a handle in the central part of the upper face of both elements (battery and inverter), which provides the user with greater proximity to the center of gravity of each element and facilitates independent handling using only one arm and keeping the body upright at all times, thus avoiding the risk of back injury. Despite the substantial weight that both elements reach, especially the battery, the presence of this upper handle solves the handling needs of both elements both for the transitions between the two operating modes mentioned (fixed and portable) and in the presence of obstacles that make difficult the use of the trolley in portable mode (floor that does not allow rolling, presence of steps, need of loading them into the trunk of a car, etc.), which make it more practical to remove them from the trolley and handle them separately, hence both preferably having the above mentioned handles.

In some embodiments, the battery is modular and comprises a first and a second fastener, for example complementary front and rear fasteners, that allow the stacking of several battery modules one in front of the other for use in portable mode.

The second battery fastener (or rear battery fastener) also allow the battery to be fixed to the wall for use in wall-mounted mode, or to be attached to the structure or frame of a transportation device, such as a trolley, for use in portable mode. In both cases, the battery is attached to the wall or to the structure of the aforementioned transportation device by means of complementary fasteners or transportation fasteners. The front fastener of the battery also allows the inverter to be coupled in portable mode.

In some embodiments, two side connection boxes containing connectors to the battery poles preferably protected by magneto-thermal circuit breakers allow to solve the modularity of the battery in both operating modes (wall-mounted and portable). In portable mode the modulation may be done by stacking the battery modules one in front of the other and connecting them in parallel by cable through same side connection boxes. In wall-mounted mode the battery modules may be attached to the wall next to each other and the connection of the battery modules is done by the same cable through adjacent connection boxes. In both modes the inverter may be connected to the first battery module of the series through the connection box. Moving the connectors and their protections to outside boxes allow also a substantial reduction of the volume of the battery box containing the battery cells.

The trolley, acting as a transportation device, may comprise rear wheels in combination with simple front supports or also in combination with front wheels. The wheels may be fixed or swivel, or a combination of fixed rear wheels and swivel front wheels. The trolley structure may also comprise a support platform and a rear vertical frame including complementary fastener for the coupling of the battery. The frame may comprise at least two vertical tubes to the upper part of which a handle is attached, which in turn comprises two vertical elements and an upper horizontal gripping element. Depending on the type of coupling with the frame, the handle may be fixed, articulated or retractable. In the fixed coupling, the vertical tubes of the frame and those of the handle are continuous and can form a single element. In the articulated case, the lower ends of the vertical handle elements are joined to the upper ends of the frame by means of horizontal pivot joints. In the retractable case, the vertical handle elements are folded into the frame elements.

Optionally, the battery and the trolley may be integrated into a single element wherein the battery comprises wheels on its base and a retractable handle that folds into ducts on the rear cover of the battery. The front fastener may still be present for coupling the inverter in front of the battery in portable mode, while the rear ones, also present, serve only to couple the battery, with the integrated handle and wheels comprised in said battery thereat, with the complementary wall-mounting fastener for use in wall-mounted mode.

In some embodiments, the inverter is mounted on a plate, for example an aluminum plate, next to a box at the bottom whose function is to integrate the protections of the inverter inputs and outputs and especially their respective connectors that allow keeping the inverter separable. The solar panels may be connected to the inverter through a direct current (DC) connector integrated in the box and the connection is protected from short circuits and overloads by a fuse. The alternating current (AC) output of the inverter may be protected from shunts by a differential breaker and from short circuits by a magneto thermic circuit breaker, and the socket, which, being electrified, is of female type, is integrated in the box. The AC input for the grid or for a fuel generator may be also made through a socket, in this case of male type, integrated in the box. The battery may be protected by a fuse or thermal magnetic circuit breaker circuit breaker integrated in the battery box.

It is important to note, that the connection box above mentioned, allow for quick and safe disconnection and reconnection of the electrical connections, facilitating this transition between modes. For example, the solar panels or the grid power supply can be connected or disconnected via the sockets integrated in the box, similarly, the AC from the grid or fuel generator can be easily disconnected.

The DC connection of the inverter to the battery can be made external to the connector box by extending the respective two-conductor output cables of the inverter and the battery and using the two male and female parts of a single DC connector at their ends. The extension of both cables must be sufficient to cover the maximum separation of both elements that occurs in wall position. Optionally, to avoid the presence of both cables hanging from both elements, it is possible to insert the inverter output two-conductor cable in the box and integrate its connector in it as well, and to do the same with the battery by replacing its cable with another connector integrated in the battery box. In this embodiment, a separate two-conductor cable section is used with complementary connectors at its ends that connect to the aforementioned connectors integrated in the connector box and in the battery, and which should be long enough to also cover the maximum separation of the aforementioned integrated connectors that occurs in the wall-mounted position.

On the back of the plate on which the inverter is mounted, there may be rear fastener or second inverter fastener. This feature enables the inverter to be connected to a inverter wall-fastener for use in the wall-mounted, or fixed operational mode. Alternatively, it allows for attachment to the aforementioned front battery fastener, facilitating use in the portable mode.

To integrate the arrangement of the present invention, also usually called power station, into a private installation, it may be necessary to cut the conductors, phase and neutral, from the output of the differential circuit breaker of the electrical board, or those from the output of the magneto thermic circuit breaker of a circuit, together with the corresponding ground conductor and extend their ends by internal or external conduit to the proximity of the inverter and its connector box on the wall. Then, on the one hand, a female type socket is coupled to the electrified ends coming from the differential or magneto thermic circuit breaker of the boards, together with the ground end connected to the electrode of the installation, which might be connected to the AC input male connector of the connector box, and on the other hand, another male type socket to the non-electrified ends of the power supply and ground of the circuits, or of the selected individual circuit, which will be connected to the AC output female connector of the connector box. The selection of the output cut-off in the electrical board, either from the differential circuit breaker or from the magneto thermic circuit breaker of one of the circuits, depends on the power of the power station inverter. In the case of inverters with a power higher than the contracted power, the cut-off can be made at the output of the differential switch. In the case of lower power inverters, the integration can be done at the circuit level, always selecting those designed to withstand a higher power than the inverter.

A second aspect of the invention refers to a system for portable energy storage and supply, said system comprising the arrangement according to any one of the embodiments aforementioned, and further comprising:
at least one energy-consuming source connected to the arrangement in the portable operational mode, wherein the energy-consuming device utilizes energy from the at least one battery module.

The energy consuming source could be any appliance connected to the arrangement in order to consume energy from the batteries, such as, mobile phones, heaters, or any electrical appliance or device which requires the energy stored in the batteries of the arrangement, this is, the arrangement working as a power station on its portable mode.

In some embodiments, the system further comprises at least an energy-generating device configured to charge the one or more battery modules, in particular said energy-generating device being at least a photovoltaic panel and/or a generator set.

A third aspect of the present invention refers to a method comprising:
providing an inverter and at least a battery module which are completely detachable and attachable to one another,
connecting the inverter to an electrical installation for self-consumption, with the inverter and the at least a battery module unattached to one another, and
transitioning to a portable operational mode by attaching the inverter and the at least a battery module to each other for transportation, disconnecting the inverter from the electrical installation.

Preferably, the method further comprises:
providing a plurality of battery module wherein each battery module is attachable to another battery module,
attaching said plurality of battery modules one in front of the other along the transversal axis, in such a way as to stacking said plurality of battery for ease of transportation, and
attaching said plurality of battery modules to the inverter by attaching one distal or proximal battery module of the stacked plurality of battery module.

### DESCRIPTION OF THE DRAWINGS

To complement the description being made and in order to aid towards a better understanding of the characteristics of the invention, in accordance with a preferred example of practical embodiment thereof, a set of drawings is attached as an integral part of said description wherein, with illustrative and non-limiting character, the following has been represented:

FIGS. 1a and 1b show respectively a front view and a rear view of the inverter according to an embodiment of the present invention, indicating the position of the inverter rear fastener, the handle, the support plate, the connector box and the separate cable and connector for the battery module.

FIGS. 2a and 2b show respectively a front view and a rear view of a battery module according to an embodiment of the present invention, indicating the position of the front and rear fastener, the handle and the side connection boxes.

FIGS. 3a and 3b show respectively a view of the trolley with the inverter and a battery module according to an embodiment of the arrangement of the present invention, said battery module connected and attached in front of each other for use in portable mode, and a view of the same trolley without the inverter and batteries to show the battery fastener.

FIG. 3.c and 3.d show side views of an embodiment of the arrangement of the present invention arranged in the portable mode, illustrating two battery modules and the cable connection of the inverter to the first module through the left connection box and the connection of both modules through their right-side connection boxes.

FIGS. 4a and 4b show respectively a view of the inverter and two battery modules connected and attached to the wall in wall mode according to an embodiment of the invention whereat the arrangement is mounted on a fixed mode, and a view of the same wall without the inverter and the batteries to illustrate the inverter-wall fastener and the battery-wall fastener.

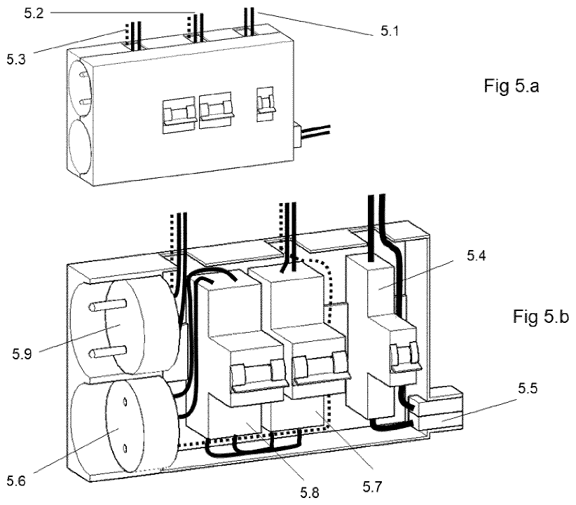

FIGS. 5a and 5b show respectively a complete connector box and the same box without cover to detail the connectors and protections according to an embodiment of the present invention.

FIG. 6.a and 6.b show the elements and details that may be modified in the private electrical installation so as to allow the integration of the arrangement of the present invention, and the restoration of the grid-only power when the arrangement is removed for use in portable mode.

### DESCRIPTION OF A WAY OF CARRYING OUT THE INVENTION

Considering the aforementioned figures and their corresponding numbering, an exemplary, non-limiting embodiment of the invention is described herein. The design parameters of the arrangement could, in some embodiments, be tailored to a 24V, 2500 W hybrid inverter (1) and two 24V100 Ah battery modules (2) based on cylindrical LiFePO4 cells. This configuration exemplifies a suitable solution for adapting the power station to the output of a 15 A magneto thermic circuit breaker (5.8) protection circuit of a private electrical installation dedicated to self-consumption.

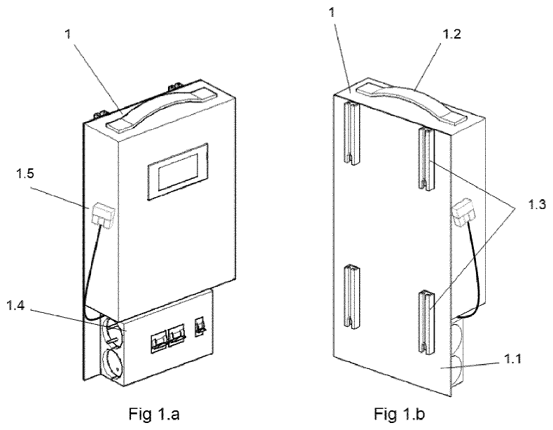

FIG. 1.a and 1.b present front and rear views of the inverter (1), mounted on an inverter back plate (1.1) made of aluminum, coupled with a connection box (1.4) at the bottom. This connection box (1.4) integrates all the protections and connectors for the inverter's inputs and outputs, as well as the inverter connector (1.5) for the battery located at the end of a two-conductor cable, which is separate from the connection box (1.4).

As illustrated in FIGS. 1a and 1b, the design of the inverter (1) employs a flattened format in which the depth dimension is minimized compared to the width and height for use in the wall-mounted mode, i.e., the fixed operational mode. The maximum depth is restricted to 10 cm, and the maximum width and height are 30 cm and 45 cm, respectively. The dimensions of the connection box (1.4) conform to this format, maintaining a similar depth while extending its width to match that of the inverter (1). This reduced-depth format of the inverter (1) allows to accommodate an inverter handle (1.2) in the central part of the upper face, offering users easy handling with just one arm and allowing them to maintain an upright posture at all times, thereby minimizing the risk of back injury.

On the back of the plate the inverter fastener (1.3) is placed so as to allow the inverter (1) to be attached in its two operation modes: portable mode on a trolley (3.2), and wall-mounted mode on a wall (4.1). The type of fastener shown in this preferred embodiment consists of four sections of tongue and groove guides that allow the fastening along a small sliding section of the female parts of the inverter (1) with the four complementary male-type fasteners located on the wall (4.3) or on the front of the battery (2.1). The support of the inverter (1) on the wall is completed with brackets (4.5).

On the back of the plate the inverter fastener (1.3) is placed so as to allow the inverter (1) to be attached in its two operation modes: portable mode on a trolley (3.2), and wall-mounted mode on a wall (4.1). The type of fastener shown in this preferred embodiment consists of four sections of tongue and groove guides that allow the fastener along a small sliding section of the female parts of the inverter (1) with the four complementary male-type fasteners located on the wall (4.3) or on the front of the battery (2.1). The support of the inverter (1) on the wall is completed with brackets (4.5).

Located on the back of the plate is the inverter fastener (1.3), which allows the inverter (1) to be attached in its two operational modes: portable mode on a transportation device (3.2), in particular a trolley, and wall-mounted mode on a wall. The fastener type depicted in this preferred embodiment comprises four sections of tongue and groove guides. These guides permit the fastener to move along a small sliding section of the female parts fasteners of the inverter (1) with four complementary male-type fasteners situated on the inverter wall-fastener (4.3) or on the battery first fastener (2.1). The support of the inverter (1) on the wall is complemented with battery wall-fasteners (4.4) materialized as a bracket (4.5).

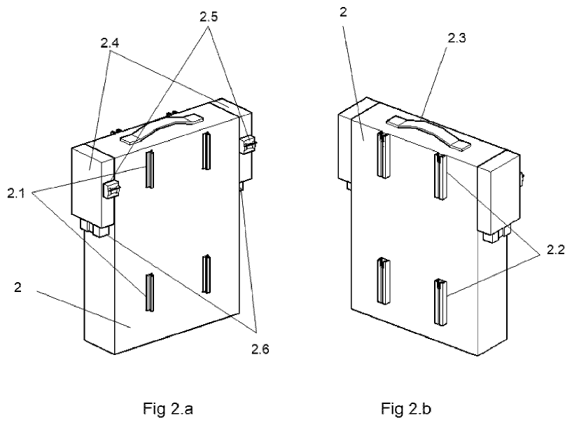

FIG. 2.a and 2.b depict front and rear views of a battery module (2). The battery module (2) has a first fastener or front battery fastener (2.1), which could be a male-type fastener, and a second fastener or rear battery fastener (2.2), which could be a female-type fastener. It also includes a top battery handle (2.3) and two side battery connection boxes (2.4) for cable connection to the inverter (1) or another battery module (2). The four battery front fasteners (2.1) allow the fastening of the inverter (1) or another battery module in portable mode. The rear battery fasteners (2.2) comprise four sections of tongue and groove guides that permit the battery module (2) to be attached to the wall for use in wall-mounted mode using the battery wall-fastener (4.4), or to be attached to the structure of a trolley or another battery module for use in portable mode. For this purpose, in such cases four complementary male type fasteners are used that are fixed to the battery wall-fastener (4.4) or to the transportation fastener (3.3). The support of each battery module (2) on the wall is completed with brackets (4.6).

Just like the inverter (1), the design of the battery module (2) is also flattened, with a reduced depth compared to its width and height, facilitating its use in the wall-mounted or fixed operational mode. The maximum depth is limited to 15 cm, while the maximum width and height are set at 45 cm and 60 cm respectively. These dimensions enable the placement of a battery handle (2.3) at the center of its upper face. This positioning facilitates single-arm handling of the battery module (2), allowing the user to maintain an upright posture at all times, thus minimizing the risk of back injuries.

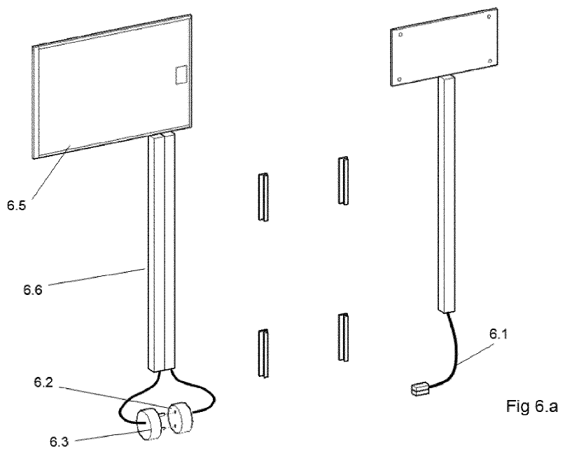

FIG. 5.a and 5.b depict an embodiment of the connector and protection box with schematic representations of its features. More specifically, solar panels can be connected to the inverter (1) via a DC input (5.1) with two conductors, which is protected against overloads and short circuits by its corresponding fuse or circuit breaker (5.4). An Anderson-type DC connector (5.5) for the two-wire cable from the solar panel is integrated within the connection box (1.4). Depending on the type and power of the panels, varistors may also be included to shield the inverter (1) from overvoltages resulting from high-voltage transients caused by lightning strikes.

The AC output (5.2) of the inverter (1), with three conductors (phase, neutral, and ground), is facilitated through a female type of socket (5.6) integrated within the connection box (1.4). As this generally requires protection independent of the private installation, it is connected through its own differential circuit breaker (5.7), which safeguards against current shunts, and a thermal magnetic circuit breaker (5.8) that protects the private installation against short circuits.

The AC input (5.3), also with three conductors, from the grid or a fuel generator does not necessitate additional protection and is connected through a male type socket (5.9) integrated within the connection box (1.4).

The DC connection to the battery (2) is made by extending the two-wire cable from the inverter (1) output and connecting it with the two-wire cable from the battery terminals, using the two male and female parts of a single DC connector at both ends. The connector (2.6) of the battery terminals and its protective magneto-thermal circuit breaker (2.5) are integrated within the side connection box (2.4) of the battery (2).

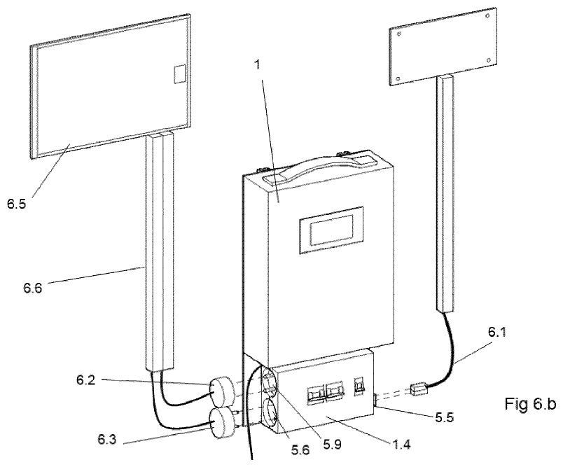

FIG. 6.a and 6.b depict the schematic elements that allow the integration of the power station within a private installation. To achieve this, the conductors (phase and neutral) from the output of the magneto-thermal circuit breaker of the electrical installation board (6.5) used for the private installation's self-consumption, are severed together with the corresponding ground connection. Their ends are then extended in a single cable through external conduits to the wall location of the inverter (1) and the connection box (1.4).

A female type socket (6.2 is then connected to the energized ends emerging from the circuit breaker of the board, along with the end of the grounding conductor linked to the electrode of the installation. These will be connected to the AC input male type socket (5.9). Another male type socket (6.3) is connected to the non-energized ends of the circuit supply, together with the end of the circuit grounding conductor. These will be connected to the AC output female type socket (5.6).

In this operational mode, the power station can function alongside fixed solar panels situated on roofs, facades, gardens, or terraces. Their two-conductor cable (6.1) is also extended, either internally or externally, to the position of the connection box (1.4). In this described setup, the inverter (1) will only utilize grid power when the energy generated by the panels and the energy stored in the battery (2) are insufficient to power the circuit loads.

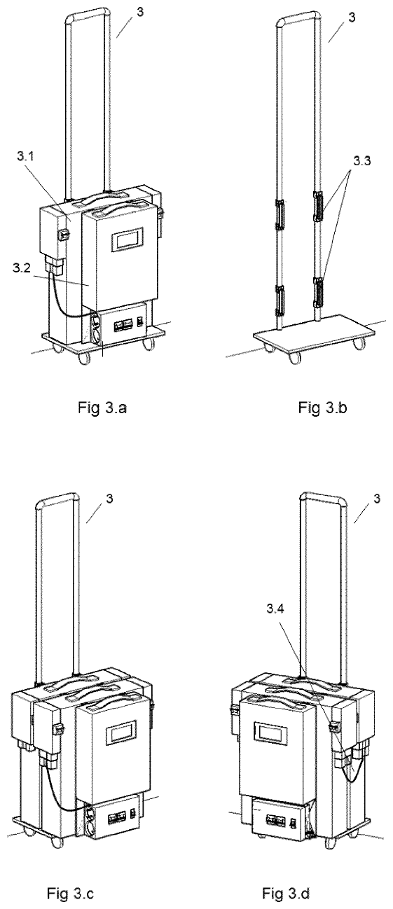

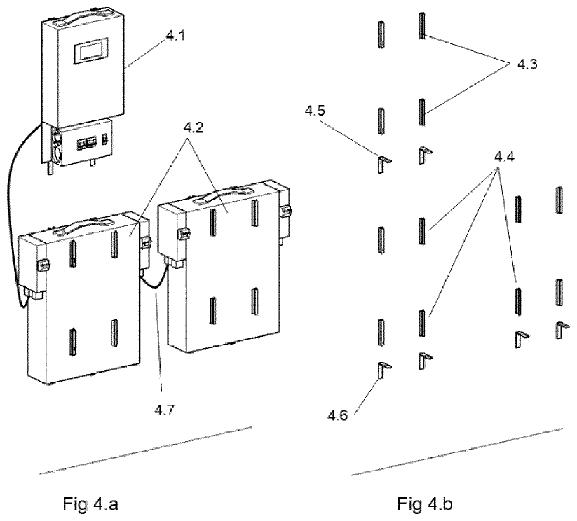

In portable mode as depicted, for example, in FIG. 3A, the power station is compatible with portable solar panels as long as they meet the same voltage specifications. In this case the AC output socket (5.6) will be used to directly power the loads of the desired devices and the AC input (5.9) can be used to connect the output of a fuel generator to ensure interrupted supply.

The transition procedures for the two operating modes of the arrangement for energy storage and supply or power station are described next.

FIG. 6.a shows the appearance that, after the described modifications, the private installation will have at the moment when the user arrives with the power station in portable mode for its installation in fixed mode. At this previous moment, as seen in FIG. 6.a, the cable end of the panel line (6.1) is loose and the male and female connectors (6.3 and 6.2) of the cut ends of the output of the selected circuit for self-consumption are coupled together (in the figure they are represented slightly separated and with dashes to represent their interconnection) so that the circuit is being supplied only with the grid.

The first step is to disconnect the circuit breaker (5.4) of the line of panels from the connection box (1.4). Then the differential circuit breaker (5.7) which disconnects the AC output (5.2) of the inverter (1) is disconnected. If there is more than one battery module (FIG. 3.c and 3.d), the circuit breakers (2.5) of each side connection box (2.4) and the corresponding connector cables (3.4) are then disconnected from the connectors (2.6) of the battery terminals, starting with those furthest away from the connection to the inverter. Then, the same is done with the circuit breaker (2.5) of the side connection box (2.4) of the first battery module. This allows to safely unplug the connector of the inverter (1.5) from the connector (2.6) of the battery terminals in the side battery connection box (2.4).

The inverter and battery modules are now separated and ready for being mounted on the wall. The user first uncouples the inverter (1) from the first battery module (2) by pulling vertically on the handle (1.2) and couples the inverter (1) to the wall by fitting its rear fastener (1.3) with the complementary ones on the wall (4.3). The user then uncouples each battery module (2) from the trolley (3) by pulling vertically on its handle (2.3) and couples them to the wall by fitting their rear fastener (2.2) with the complementary ones on the wall (4.4). In this situation the next step consists in reconnecting already the connector cables (4.7) with the connectors (2.6) of the battery terminals of each adjacent battery side connection box (2.4) and the connector (1.5) of the inverter with the connector (2.6) of the battery terminals of the other side connection box (2.4).

The user now goes to the board (6.5) and, making sure that all the devices sensitive to power drops in the circuit are switched off (electronic devices in general), disconnects the magneto-thermal circuit breaker of the circuit and then safely disconnects the male and female connectors (6.3 and 6.2) from the cut ends of the circuit output. FIG. 6. b shows the 3 connections that are then made by the user: the female socket (6.2) of the circuit breaker output of the board is connected to the male AC input connector (5.9) of the connector box (1. 4); the male type socket (6.3) of the circuit is connected to the female AC output connector (5.6); and the DC connector (6.1) of the line of panels is connected to its corresponding connector (5.5) integrated in the connection box (1.4).

The user finally reconnects the protection circuit breakers in the following order: first the circuit breakers (2.5) of each side connection box of the battery modules are connected starting with the furthest ones and ending with the one connected with the inverter that initializes its electronics, then the circuit breaker of the panel line (5.4), then the magneto-thermal circuit breaker circuit breaker (6.5) of the board, and finally the differential circuit breaker (5.2) of the AC output of the inverter.

To swap from fixed mode to portable mode the procedure is the same as described above but in reverse order. The result leaves the circuit powered only by the grid, as shown in FIG. 6.a, and the power station is configured in portable mode as shown in FIG. 3.a.

### LIST OF REFERENCE SIGNS

(1) Inverter
(1.1) Inverter back plate
(1.2) Inverter handle
(1.3) Inverter fastener or rear inverter fastener
(1.4) Connection box
(1.5) Inverter connector
(2) Battery module
(2.1) First battery fastener or front battery fastener
(2.2) Second battery fastener or rear battery fastener
(2.3) Battery handle
(2.4) Battery connection box
(2.5) Circuit breakers
(2.6) Connector of the battery terminals
(3.2) transportation device
(3.3) Transportation fastener
(4.3) Inverter wall-fastener
(4.4) Battery wall-fastener
(4.5) bracket
(5.2) Connector box AC output
(5.3) Connector box AC input
(5.4) Connector box fuse or circuit breaker
(5.5) Connector box DC input
(5.6) Connector box female type socket
(5.7) Connection box differential circuit breaker
(5.8) Connection box magneto thermic circuit breaker
(5.9) Connector box male type socket
(6.1) Photovoltaic panel connection cable
(6.2) Board female type socket
(6.3) Board male type socket
(6.5) Electrical installation board

1. Arrangement for energy storage and supply, comprising an inverter and at least a battery module, wherein the inverter and the at least a battery module are attachable and detachable in such a way as to determine:
a fixed operational mode, with the inverter and the at least a battery module unattached to one another, wherein the inverter is configured to be connected to an electrical installation for self-consumption, in particular self-consumption with photovoltaic panels,
a portable operational mode for stand-alone use, with the inverter and the at least a battery module attached to one another for ease of transportation, in particular with the inverter electrically disconnected from the electrical installation and physically removed thereof,
wherein the at least a battery module comprises a first battery fastener attachable to an inverter fastener comprised in the inverter, wherein the first fastener and the inverter fastener are configured to be used in the portable mode with the inverter attached to the at least a battery module thereof,
wherein the inverter comprises an inverter wall-fastener intended to be attached to a wall or to any vertical surface during the fixed operational mode, wherein the inverter fastener is further attachable with said wall-fastener.

2. (canceled)

3. The arrangement of claim 1, further comprising an inverter wall-fastener intended to be attached to a wall or to any vertical surface during the fixed operational mode, wherein the inverter further comprises a second inverter fastener attachable with the inverter wall-fastener.

4. The arrangement of claim 1, further comprising a battery wall-fastener intended to be attached to a wall or to any vertical surface during the fixed operational mode, wherein the at least a battery module comprises a second battery fastener attachable with the battery wall-fastener, said fastener configured to be used in the fixed operation mode, in particular, with the at least a battery module electrically connected but physically unattached to the inverter during the fixed operational mode.

5. The arrangement of claim , wherein the second battery fastener is further attachable to a transporting device comprising transportation fastener attachable to said battery second fastener, in such a way that transport is facilitated during the portable operational mode.

6. The arrangement of claim 5, wherein the transportation device comprises a trolley, wherein said trolley comprises a plurality of wheels and a frame provided with the transportation fastener attachable with the second fastener of the at least a battery module.

7. The arrangement of claim 1, further comprising a battery wall-fastener intended to be attached to a wall or to any vertical surface in the fixed operational mode, wherein the battery first fastener is attachable with the battery wall-fastener, said fastener configured to be used in the fixed operation mode, in particular, with the at least one battery module electrically connected but unattached to the inverter during the fixed operational mode.

8. The arrangement of claim 1, comprising a plurality of battery modules, each of the battery modules comprising battery first fastener and battery second fastener configured to be attached to one another, in such a way that the plurality of battery modules is configured to be stacked one in front of the other in the portable operational mode.

9. The arrangement of claim 8, wherein the at least a battery module of the plurality of battery modules, comprises one or more side connection boxes each comprising connectors of the battery terminals configured to be used for connection with the inverter or with another battery module.

10. The arrangement of claim 1, comprising:
a plurality of battery modules, each battery module comprising battery second fastener, and
a battery wall-fastener attachable to the second fastener, said battery wall-fastener intended to be attached to a wall or to any vertical surface in the fixed operational mode,
in such a way as to allow each battery module of the plurality of battery modules to be affixed to the wall or vertical surface independently side-by-side.

11. The arrangement of claim 1, wherein:
the at least a battery has a flattened shape with a maximum depth of 15 cm, in particular with the at least a battery comprising a maximum depth of 10 cm, and/or
the inverter has a flattened shape with a maximum depth of 12 cm.

12. The arrangement of claim 1, wherein the inverter and/or the at least a battery module comprise a handle at a top portion configured to provide the user with ergonomic handling with one arm and keeping the body upright, in particular the at least a battery module further comprising at least two wheels, such that once the inverter has been attached thereto said wheels and the handle facilitate the transport thereof in the portable operational mode devoid of a transportation device.

13. The arrangement of claim 1, comprising a connection box integrating the connectors of the inverter inputs and outputs allowing the disconnection of the inverter for use in both fixed and portable operational modes, and comprising at least one DC input connector for photovoltaic panels, one AC output connector for powering loads and one AC input connector for the grid or for a fuel generator.

14. A system for portable energy storage and supply, said system comprising the arrangement of claim 1, and further comprising:
at least one energy-consuming source connected to the arrangement in the portable operational mode, wherein the energy-consuming device utilizes energy from the at least one battery module, in particular further comprising at least an energy-generating device configured to charge the at least battery module, in particular said energy-generating device being at least a photovoltaic panel, or a generator set.

15. (canceled)
